(19) United States
(12) Patent Application Publication
(10) Pub. No.: US 2026/0212902 A1
(43) Pub. Date: Jul. 23, 2026

(54) SEMICONDUCTOR MEMORY DEVICES, MEMORY SYSTEMS AND MEMORY DIES

(71) Applicant: Samsung Electronics Co., Ltd., Suwon-si (KR)

(72) Inventors: Sungwoo Yoon, Suwon-si (KR); Daehyun Kwon, Suwon-si (KR); Hyejung Kwon, Suwon-si (KR); Yongin Park, Suwon-si (KR)

(21) Appl. No.: 19/292,694

(22) Filed: Aug. 6, 2025

(30) Foreign Application Priority Data
Jan. 20, 2025 (KR) 10-2025-0007888

(51) Int. Cl. G11C 7/10

(52) U.S. Cl. CPC G11C 7/1048; G11C 2207/2254

(57) ABSTRACT

A semiconductor memory device includes an external resistor in a board and a memory dies on the board. A first memory die of the memory dies is designated as a master die and other memory dies of the memory dies are designated as slave dies. The master die includes a first output driver and a first communication pad. The master die, determines a first control code set associated with the first output driver based on a first power supply voltage, latches the first control code set, generates a first done signal indicating that the first control code is set, transmits the first done signal to a first slave die through the first communication pad, determines a second control code set associated with the first output driver based on a second power supply voltage based on the first done signal and latches the second control code set.

### CROSS-REFERENCE TO RELATED APPLICATION

This application claims priority under 35 U.S.C. § 119 to Korean Patent Application No. 10-2025-0007888, filed on Jan. 20, 2025, in the Korean Intellectual Property Office, the disclosure of which is incorporated by reference herein in its entirety.

### TECHNICAL FIELD

The present disclosure relates to memory devices, and more particularly, to semiconductor memory devices including multi-dies, memory systems including the same, and memory dies.

### BACKGROUND

As the operating speed of semiconductor memory devices has increased, swing width of signals (e.g., the range of values of the signals) interfaced between a semiconductor memory device and a memory controller has generally decreased. However, as swing width has decreased, signals transferred between the semiconductor memory device and the memory controller may be more easily distorted by impedance mismatch caused by process, voltage, and temperature (PVT) variations. An impedance calibration operation for adjusting output impedance and/or a termination impedance of the semiconductor memory device may be employed at transmitting and/or receiving stages of the semiconductor memory device. The impedance calibration operation may be referred to as an input/output (I/O) offset cancellation operation or an impedance equilibrium (ZQ) calibration operation.

### SUMMARY

Some example implementations provide a semiconductor memory device including a plurality of memory dies capable of performing an impedance calibration operation associated with a plurality of power domains in advance.

Some example implementations provide a memory system that includes a semiconductor memory device including a plurality of memory dies capable of performing an impedance calibration operation associated with a plurality of power domains in advance.

Some example implementations provide a memory die capable of performing an impedance calibration operation associated with a plurality of power domains in advance.

According to some example implementations, a semiconductor memory device includes an external resistor in a board and a plurality of memory dies on the board and connected to the external resistor. The plurality of memory dies include a master die and a plurality of slave dies. The master die includes a first output driver and a first communication pad. The master die, during an impedance calibration interval, determines, based on a first power supply voltage, a first control code set associated with the first output driver, latches the first control code set, generates a first done signal indicating that the first control code is determined, transmits the first done signal to a first slave die of the plurality of slave dies through the first communication pad, determines, based on a second power supply voltage, a second control code set associated with the first output driver in response to the first done signal and latches the second control code set. The first slave die includes a second output driver and a second communication pad. The first slave receives, from the master die, the first done signal through the second communication pad, based on the first done signal, determines, based on the first power supply voltage, a third control code set associated with the second output driver, latches the third control code set, generates a second done signal indicating that the third control code is determines, based on the second done signal, determines, based on the second power supply voltage, a fourth control code set associated with the second output driver and latches the fourth control code set.

According to some example implementations, a memory system includes a semiconductor memory device including a plurality of memory dies and a memory controller to control the semiconductor memory device. The semiconductor memory device includes an external resistor in a board and a plurality of memory dies on the board and connected to the external resistor. The plurality of memory dies include a master die and a plurality of slave dies. The master die includes a first output driver and a first communication pad. The master die, during an impedance calibration interval, determines, based on a first power supply voltage, a first control code set associated with the first output driver, latches the first control code set, generates a first done signal indicating that the first control code is determined, transmits the first done signal to a first slave die of the plurality of slave dies through the first communication pad, determines, based on a second power supply voltage, a second control code set associated with the first output driver in response to the first done signal and latches the second control code set.

According to some example implementations, a memory die includes an output driver, an impedance calibration circuit, a power selection circuit, a data input/output (I/O) circuit including the output driver, a first power switch and a second power switch. The impedance calibration circuit is connected to an external resistor through an impedance pad, and, during an impedance calibration interval, determines, based on a first power supply voltage, a first control code set associated with a driving strength of the output driver, latches the first control code set, generates a first done signal indicating that the first control code is determined, transmits the first done signal through a communication pad, based on the first done signal, determines, based on a second power supply voltage, a second control code set associated with the driving strength of the output driver and latches the second control code set. The power selection circuit receives the first power supply voltage and the second power supply voltage, provides the first power supply voltage to the impedance calibration circuit and provides, based on the first done signal, the second power supply voltage to the impedance calibration circuit. The first power switch provides the first power supply voltage to the data I/O circuit based on a power selection signal. The second power switch provides the second power supply voltage to the data I/O circuit based on an inverted version of the power selection signal.

Accordingly, the master die and the slave dies are provided in the same board, are commonly connected to the external resistor through respective one of impedance pads and perform the impedance calibration operation sequentially by communicating with each other through the communication pads. Therefore, when the data I/O circuit operates based on at least two different power supply voltages, the semiconductor memory device may enhance performance because each of the master die and the slave dies determines control code sets associated with the different power supply voltages in advance during an impedance calibration interval, latches the control code sets therein in advance and selects corresponding one of the control code sets based on a provided power supply voltage without additional calibration time interval when a power domain is changed.

### BRIEF DESCRIPTION OF THE DRAWINGS

The above and other features of the present disclosure will be more clearly understood by describing in detail example implementations thereof with reference to the accompanying drawings.

FIG. 1 is a block diagram illustrating a memory system according to some example implementations.

FIG. 2 is a block diagram illustrating an example of the master die in the semiconductor memory device in FIG. 1 according to some example implementations.

FIG. 3 illustrates an example of a first bank array in the master die of FIG. 2 according to some example implementations.

FIG. 4 illustrates an example of a data I/O circuit in the master die of FIG. 2 according to some example implementations.

FIG. 5 is a circuit diagram illustrating an output driver in the data I/O circuit in FIG. 4 according to example implementations.

FIG. 6 is a diagram for explaining an operation of a data output circuit in FIG. 5 according to some example implementations.

FIG. 7 is a block diagram illustrating an example of the semiconductor memory device in the memory system of FIG. 1 according to some example implementations.

FIG. 8 is a timing diagram illustrating an impedance calibration operation of the semiconductor memory device of FIG. 7 according to some example implementations.

FIG. 9 illustrates a block diagram illustrating an impedance calibration circuit in the master die in FIG. 7 according to some example implementations.

FIG. 10A is a block diagram illustrating an example of a calibration circuit in the impedance calibration circuit of FIG. 9 according to some example implementations.

FIG. 10B is a block diagram illustrating an example of the first counter in FIG. 10A according to some example implementations.

FIG. 11 is a timing diagram illustrating an example operation of the impedance calibration circuit in FIGS. 7 and 9 according to some example implementations.

FIG. 12 is a block diagram illustrating an impedance calibration circuit in the first slave die in FIG. 7 according to example implementations.

FIGS. 13 and 14 illustrate that the impedance calibration operation is performed in the semiconductor memory device in FIG. 1, according to some example implementations.

FIG. 15 illustrates that a background impedance calibration operation is performed during an idle period in the semiconductor memory device in FIG. 13, according to some example implementations.

FIG. 16 is a flowchart illustrating a method of operating a semiconductor memory device including multi-dies according to some example implementations.

FIG. 17 is a schematic diagram of a multi-chip package including a semiconductor memory device according to some example implementations.

FIG. 18 is a block diagram illustrating a semiconductor memory device according to some example implementations.

FIG. 19 is a configuration diagram illustrating a semiconductor package including the stacked memory device according to example implementations.

FIG. 20 is an example of a computing system when a memory system according to example implementations corresponds to a Type 3 memory system defined by a compute express link (CXL) protocol.

### DETAILED DESCRIPTION

Example implementations of the present disclosure will be described more fully hereinafter with reference to the accompanying drawings. Like reference numerals may refer to like elements throughout this application.

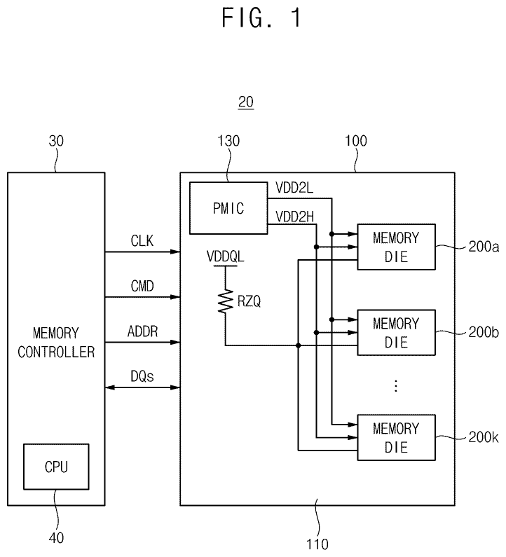

FIG. 1 is a block diagram illustrating a memory system according to some example implementations.

Referring to FIG. 1, a memory system 20 may include a memory controller 30 and a semiconductor memory device 100. The semiconductor memory device 100 may include a plurality of memory dies 200a, 200b, . . . , 200k (which are denoted as 200a-200k, hereinafter), where k is an integer greater than two. In some example implementations, each of the memory dies 200a-200k may be referred to as a memory chip. A first memory die (for example, the memory die 200a) of memory dies 200a-200k may be indicated by a master die and rest (for example, the memory dies 200b-200k) of the memory dies 200a-200k rather than the memory die 200a may be indicated as a plurality of slave dies. That is, the plurality of memory dies 200a, 200b, . . . , 200k may include the master die 200a and a plurality of slave dies 200b-200k.

The memory controller 30 may control an overall operation of the memory system 20. The memory controller 30 may control an overall data exchange between an external host and the plurality of memory dies 200a-200k. For example, the memory controller 30 may write data in the plurality of memory dies 200a-200k or read data from the plurality of memory dies 200a-200k in response to a request from the host. The memory controller 30 may issue operation commands to the plurality of memory dies 200a-200k for controlling the plurality of memory dies 200a-200k.

The memory controller 30 may transmit, to the memory dies 200a-200k, control signals such as a clock signal CLK, a command CMD, an address ADDR, and data signals DQs. The memory controller 30 may also receive the data signals DQs from the memory dies 200a-200k. The memory controller 30 may transmit a write command, a read command, and an impedance calibration command to each of the memory dies 200a-200k. Each of the memory dies 200a-200k may perform a write operation in response to the write command, a read operation in response to the read command, and an impedance calibration operation in response to the impedance calibration command.

In some example implementations, each of the plurality of memory dies 200a-200k may be a dynamic random access memory (DRAM), such as a double data rate synchronous dynamic random access memory (DDR SDRAM), a low power double data rate synchronous dynamic random access memory (LPDDR SDRAM), or the like.

The plurality of memory dies 200a-200k may be commonly connected to an external resistor RZQ provided (or, formed) in a board 110. For example, the board 110 may be a circuit board, a package substrate or an interposer. The external resistor RZQ may be connected to a power supply voltage VDDQL. In some example implementations, the external resistor RZQ may be connected to a ground voltage. The semiconductor memory device 100 may further include a power management integrated circuit (PMIC) 130.

The PMIC 130 may generate a first power supply voltage VDD2L and a second power supply voltage VDD2H based on an input voltage (not illustrated) from the memory controller 30 and may provide the first power supply voltage VDD2L and the second power supply voltage VDD2H to the memory dies 200a-200k. The first power supply voltage VDD2L and the second power supply voltage VDD2H may be referred to as a plurality of power domains.

In some example implementations, the second power supply voltage VDD2H may be greater than the first power supply voltage VDD2L. The PMIC 130 may provide the first power supply voltage VDD2L to the memory dies 200a-200k when the memory dies 200a-200k operate with a first frequency and may provide the second power supply voltage VDD2H to the memory dies 200a-200k when the memory dies 200a-200k operate with a second frequency greater than the first frequency.

The memory controller 30 may include a central processing unit (CPU) 40 to control operation of the memory controller 30. The memory controller 30 may provide an impedance calibration command to the master die 200a among the plurality of memory dies 200a-200k. The master die 200a may perform a first impedance calibration operation and may transmit (e.g., send or output), to a first slave die 200b among the plurality of slave dies 200b-200k through a first communication pad, a first done signal indicating completion of the first impedance calibration operation or that a control code set based on one of a plurality of power supply volage is set (e.g., determined)

The first slave die 200b may receive the first done signal through a second communication pad, may perform a second impedance calibration operation based on the first done signal and may transmit, to a second slave die among the plurality of slave dies 200b-200k through the second communication pad, a second done signal indicating completion of the second impedance calibration operation or that a control code set based on one of a plurality of power supply volage is determined. The second slave die may be adjacent to the first slave die 200b.

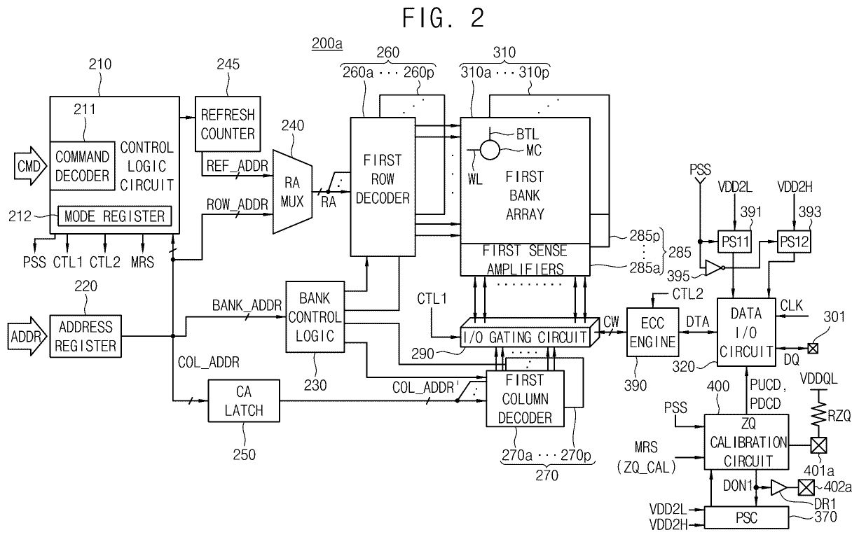

FIG. 2 is a block diagram illustrating an example of the master die in the semiconductor memory device in FIG. 1 according to some example implementations.

Referring to FIG. 2, the master die 200a may include a control logic circuit 210, an address register 220, a bank control logic 230, a row address multiplexer 240, a column address latch 250, a row decoder 260, a column decoder 270, a memory cell array 310, a sense amplifier unit 285, an input/output (I/O) gating circuit 290, a refresh counter 245, an error correction code (ECC) engine 390, a data I/O circuit 320, an impedance (ZQ) calibration circuit 400, a power selection circuit PSC 370, a driver DR1, a first power switch PS11 391, a second power switch PS12 393 and an inverter 395.

The memory cell array 310 may include first through sixteenth bank arrays 310a-310p. The row decoder 260 may include first through sixteenth row decoders 260a-260p respectively coupled to the first through sixteenth bank arrays 310a-310p. The column decoder 270 may include first through sixteenth column decoders 270a-270p respectively coupled to the first through sixteenth bank arrays 310a-310p. The sense amplifier unit 285 may include first through sixteenth sense amplifiers 285a-285p respectively coupled to the first through sixteenth bank arrays 310a-310p. The first through sixteenth bank arrays 310a-310p, the first through sixteenth row decoders 260a-260p, the first through sixteenth column decoders 270a-270p, and first through sixteenth sense amplifiers 285a-285p may form first through sixteenth banks.

The first through sixteenth bank arrays 310a-310p, the first through sixteenth row decoders 260a-260p, the first through sixteenth column decoders 270a-270p, and the first through sixteenth sense amplifiers 285a-285p may form first through sixteenth banks. Each of the first through sixteenth bank arrays 310a-310p may include a plurality of memory cells MC, formed at intersections of a plurality of word-lines WL and a plurality of bit-line BTL.

Although the master die 200a is illustrated in FIG. 2 as including sixteen banks, example implementations of the present disclosure are not limited thereto, and the master die 200a may include any number of banks.

The address register 220 may receive the address ADDR including a bank address BANK_ADDR, a row address ROW_ADDR, and a column address COL_ADDR from the memory controller 30. The address register 220 may provide the received bank address BANK_ADDR to the bank control logic 230, provide the received row address ROW_ADDR to the row address multiplexer 240, and provide the received column address COL_ADDR to the column address latch 250.

The bank control logic 230 may generate bank control signals in response to the bank address BANK_ADDR. One of the first through sixteenth row decoders 260a-260p corresponding to the bank address BANK_ADDR may be activated in response to the bank control signals, and one of the first through sixteenth column decoders 270a-270p corresponding to the bank address BANK_ADDR may be activated in response to the bank control signals.

The row address multiplexer 240 may receive the row address ROW_ADDR from the address register 220, and may receive a refresh row address REF_ADDR from the refresh counter 245. The row address multiplexer 240 may selectively output one of the row address ROW_ADDR and the refresh row address REF_ADDR as a row address RA. The row address RA that is output from the row address multiplexer 240 may be applied to the first through sixteenth row decoders 260a-260p.

The refresh counter 245 may sequentially increase or decrease the refresh row address REF_ADDR under control of the control logic circuit 210.

The activated one of the first through sixteenth row decoders 260a-260p may decode the row address RA that is output from the row address multiplexer 240, and may activate a word-line corresponding to the row address RA. For example, the activated row decoder may apply a word-line driving voltage to the word-line corresponding to the row address RA.

The column address latch 250 may receive the column address COL_ADDR from the address register 220, and may temporarily store the received column address COL_ADDR. In some example implementations, in a burst mode, the column address latch 250 may generate column addresses COL_ADDR′ that increment from the received column address COL_ADDR. The column address latch 250 may apply the temporarily stored or generated column address COL_ADDR′ to the first through sixteenth column decoders 270a-270p.

The activated one of the first through sixteenth column decoders 270a-270p may decode the column address COL_ADDR′ that is output from the column address latch 250, and may control the I/O gating circuit 290 to output data corresponding to the column address COL_ADDR.

The I/O gating circuit 290 may include circuitry for gating input/output data. The I/O gating circuit 290 may further include read data latches for storing data that is output from the first through sixteenth bank arrays 310a-310p, and write drivers for writing data to the first through sixteenth bank arrays 310a-310p.

A codeword CW that is read from one bank array of the first through sixteenth bank arrays 310a-310p may be sensed by a sense amplifier coupled to the one bank array from which the data is to be read, and may be stored in the read data latches. The codeword CW stored in the read data latches may be provided to the ECC engine 390. The ECC engine 390 may perform an ECC decoding on the codeword CW to provide the data DTA to the data I/O circuit 320. The data I/O circuit 320 may convert the data DTA to the data signal DQ and may transmit the data signal DQ to the memory controller 30 through a data I/O pad 301.

The data signal DQ to be written in one bank array of the first through sixteenth bank arrays 310a-310p may be provided to the data I/O circuit 320 from the memory controller 30 through the data I/O pad 301. The data I/O circuit 320 may convert the data signal DQ to the data DTA and provide the data DTA to the ECC engine 390. The ECC engine 390 may perform an ECC encoding on the data DTA to generate parity bits and the ECC engine 390 may provide the data DTA and the parity bits to the I/O gating circuit 290. The I/O gating circuit 290 may write the data DTA and the parity bits in a sub-page in one bank array through the write drivers.

The data I/O circuit 320 may drive bits of the data DTA based on a pull-up control code PUCD and a pull-down control code PDCD from the impedance calibration circuit 400 to generate the data signal DQ having a target output high level (VOH) voltage level and provide the data signal DQ to the memory controller 30 through the data I/O pad 301.

The data I/O circuit 320 may receive the first power supply voltage VDD2L or the second power supply voltage VDD2H according to an operating frequency of the master die 200a. The first power switch 391 may provide the first power supply voltage VDD2L to the data I/O circuit 320 based on a power selection signal PSS. The inverter 395 may provide an inverted version of the power selection signal PSS to the second power switch 393 by inverting the power selection signal PSS. The second power switch 393 may provide the second power supply voltage VDD2H to the data I/O circuit 320 based on the inverted version of the power selection signal PSS.

The ECC engine 390 may perform an ECC encoding and ECC decoding on the data DTA based on a second control signal CTL2 from the control logic circuit 210.

The impedance calibration circuit 400 may be connected to the external resistor RZQ through an impedance (ZQ) pad 401a and the external resistor RZQ may be coupled to the power supply voltage VDDQL. In some example implementations, the external resistor RZQ may be coupled to the ground voltage. The impedance calibration circuit 400 may be connected to a first communication pad 402a that is connected to a second communication pad of a first slave die 200b.

The power selection circuit 370 may receive the first power supply voltage VDD2L and the second power supply voltage VDD2H, may provide one of the first power supply voltage VDD2L and the second power supply voltage VDD2H to the impedance calibration circuit 400 and may provide the other of the first power supply voltage VDD2L and the second power supply voltage VDD2H to the impedance calibration circuit 400 based on a first done signal DON1.

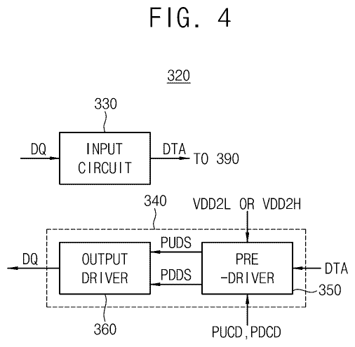

Based on a mode register set signal MRS or an impedance calibration command ZQ_CAL, the impedance calibration circuit 400 (e.g., a ZQ calibration circuit), during an impedance calibration interval, may set (e.g., determine) a first control code set associated with a driving strength of a first output driver (360 in FIG. 4) based on the first power supply voltage VDD2L, may latch the first control code set therein, may generate the first done signal DON1 indicating that the first control code is determined, may transmit the first done signal DON1 to an outside of the master die 200a (e.g., a first slave die) through the first communication pad 402a, based on the first done signal DON1, may determine a second control code set associated with the driving strength of the first output driver based on the second power supply voltage VDD2H and may latch the second control code set therein.

The impedance calibration circuit 400, during a normal mode, may provide the data I/O circuit 320 with one of the first control code set and the second control code set as the pull-up control code PUCD and the pull-down control code PDCD based on the power selection signal PSS associated with selecting the first power supply voltage VDD2L or the second power supply voltage VDD2H.

The impedance calibration circuit 400 may provide the driver DR1 with a first done signal DON1 indicating that the first control code set is determined (e.g., set). The driver DR1 may be connected to the impedance pad 401a and may transmit the first done signal DON1 to the first slave die 200b through the impedance pad 401a. The impedance pad 401a may be referred to as a first impedance pad.

The control logic circuit 210 may control operations of the master die 200a. For example, the control logic circuit 210 may generate control signals for the master die 200a in order to perform a write operation, a read operation or an impedance calibration operation. The control logic circuit 210 may include a command decoder 211 that decodes the command CMD received from the memory controller 300, and may include a mode register 212 that sets an operation mode of the master die 200a.

The command decoder 211 may generate the control signals corresponding to the command CMD by decoding a write enable signal, a row address strobe signal, a column address strobe signal, a chip select signal, etc. The control logic circuit 210 may generate a first control signal CTL1 to control the I/O gating circuit 290, may generate the second control signal CTL2 to control the ECC engine 390, may generate the mode register set signal MRS to control the impedance calibration circuit 400, may generate the power selection signal PSS associated with selecting the first power supply voltage VDD2L or the second power supply voltage VDD2H and may provide the power selection signal PSS to the first power switch 391, the second power switch 393 and the impedance calibration circuit 400. In some example implementations, the power selection signal PSS may be provided from the memory controller 30. In some example implementations, the power selection signal PSS may be associated with an operating frequency of the master die 200a or may be associated with an operating frequency of the memory dies 200a-200k

Configuration of each of the slave dies 200b-200k may be substantially the same as or similar with a configuration of the master die 200a of FIG. 2.

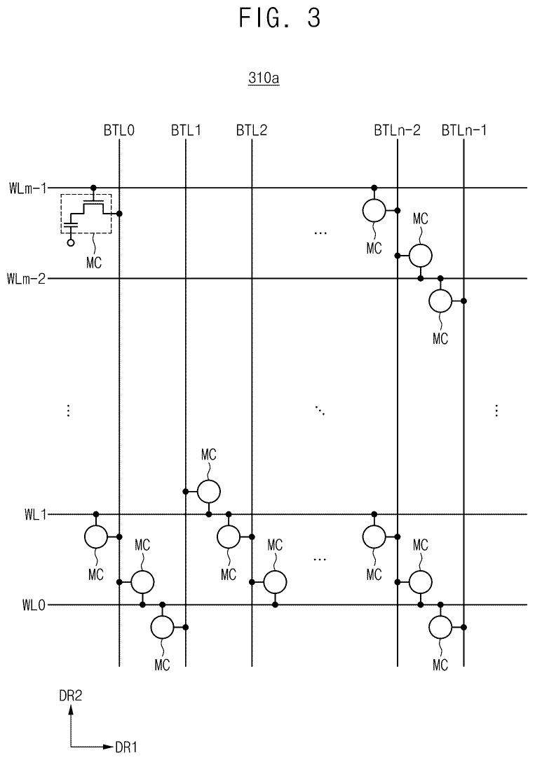

FIG. 3 illustrates an example of a first bank array in the master die of FIG. 2 according to some example implementations.

Referring to FIG. 3, the first bank array 310a may include a plurality of word-lines WL0-WLm-1 (m is a natural number greater than two), a plurality of bit-lines BTL0-BTLn-1 (n is a natural number greater than two), and a plurality of memory cells MCs disposed at intersections between the word-lines WL0-WLm-1 and the bit-lines BTL0-BTLn-1. Each of the memory cells MCs may include a cell transistor coupled to each of the word-lines WL0-WLm-1 and each of the bit-lines BTL0-BTLn-1 and a cell capacitor coupled to the cell transistor. Each of the memory cells MCs may have a DRAM cell structure. Each of the word-lines WL0-WLm-1 extends in a first direction DR1 and each of the bit-lines BTL1-BTLn-1 extends in a second direction DR2 crossing the first direction DR1.

The word-lines WL0-WLm-1 coupled to the plurality of memory cells MCs may be referred to as rows of the first bank array 310a and the bit-lines BTL0-BTLn-1 coupled to the plurality of memory cells MCs may be referred to as columns of the first bank array 310a.

FIG. 4 illustrates an example of the data I/O circuit in the master die of FIG. 2 according to some example implementations.

Referring to FIG. 4, the data I/O circuit 320 may include a data input circuit 330 and a data output circuit 340. The data output circuit 340 may include a pre-driver 350 and an output driver 360.

The data input circuit 330 may receive the data signal DQ from the memory controller 30, may convert the data signal DQ to the data DTA, and may provide the data DTA to the ECC engine 390. The data output circuit 340 may convert data DTA from the ECC engine 390 to the data signal DQ and provide the data signal DQ to the memory controller 30.

The pre-driver 350 may receive the data DTA, may operate based on the first power supply voltage VDD2L or the second power supply voltage VDD2H, may generate a pull-up driving signal PUDS and a pull-down driving signal PDDS based on the pull-up control code PUCD and the pull-down control code PDCD, and may provide the pull-up driving signal PUDS and the pull-down driving signal PDDS to the output driver 360. When the pre-driver 350 receives the first power supply voltage VDD2L, bits having logic high levels of the pull-up driving signal PUDS and the pull-down driving signal PDDS may have a voltage level of the first power supply voltage VDD2L. When the pre-driver 350 receives the second power supply voltage VDD2H, bits having logic high levels of the pull-up driving signal PUDS and the pull-down driving signal PDDS may have a voltage level of the second power supply voltage VDD2H.

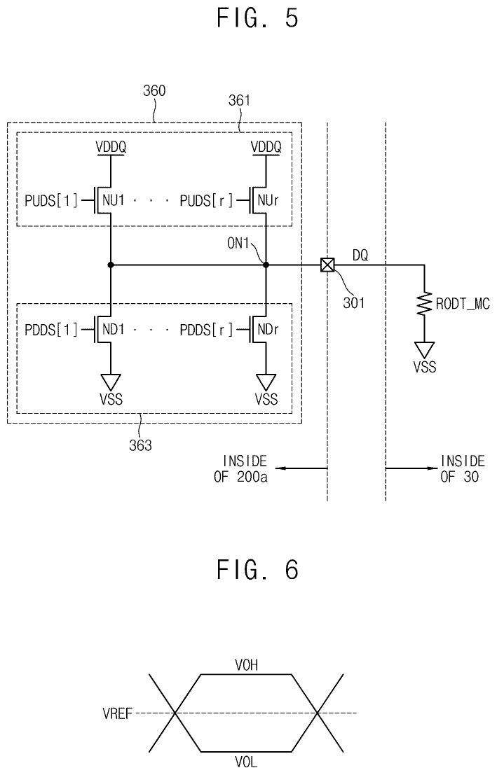

For example, when the data DTA is at a (logic) high level, the pre-driver 350 may buffer the pull-up control code PUCD and generate the pull-up driving signal PUDS to be substantially the same as the pull-up control code PUCD, and may generate the pull-down driving signal PDDS for turning off all transistors included in a pull-down driver (such as a pull-down driver 363 shown in FIG. 5) of the output driver 360. Contrarily, when the data DTA is at a (logic) low level, the pre-driver 350 may buffer the pull-down control code PDCD and generate the pull-down driving signal PDDS to be substantially the same as the pull-down control code PDCD, and generate the pull-up driving signal PUDS for turning off all transistors included in a pull-up driver (such as a pull-up driver 361 shown in FIG. 5) of the output driver 360. The pre-driver 350 may determine a current generated by the pull-up driver 361 and a resistance of the pull-down driver 363 (shown in FIG. 5) when the output driver 360 outputs the data signal DQ.

FIG. 5 is a circuit diagram illustrating an output driver in the data I/O circuit in FIG. 4 according to some example implementations.

Referring to FIG. 5, the output driver 360 may include the pull-up driver 361 and the pull-down driver 363.

The pull-up driver 361 may include first through r-th (r is a natural number greater than one) pull-up transistors NU1 through NUr connected between the power supply voltage VDDQL and an output node ON1. Each of the first through r-th pull-up transistors NU1 through NUr may be an n-channel metal oxide semiconductor (NMOS) transistor.

The pull-down driver 363 may include first through r-th pull-down transistors ND1 through NDr connected between the output node ON1 and a ground voltage VSS. Each of the first through r-th pull-down transistors ND1 through NDr may be an NMOS transistor.

When the data DTA is at the high level, the pull-up driver 361 may receive the pull-up driving signal PUDS (e.g., PUDS[1] through PUDS[r]) corresponding to the pull-up control code PUCD from the pre-driver 350 and generate the current determined e.g., set) by the pull-up control code PUCD. The pull-down transistors ND1 through NDr included in the pull-down driver 363 may all be turned off according to the pull-down driving signal PDDS (e.g., PDDS[1] through PDDS[r]).

When the data DTA is at the high level, the current generated by the pull-up driver 361 may be transmitted to an on-die termination (ODT) resistor RODT_MC in the memory controller 30 via the data I/O (or DQ) pad 301. The data signal DQ that the ODT resistor RODT_MC receives is determined by the current generated by the pull-up driver 361 and the ODT resistor RODT_MC, and the data signal DQ has the target VOH voltage that has been adjusted according to the pull-up control code PUCD generated by the impedance calibration circuit 400. The target VOH voltage may be referred to as a reference VOH voltage.

When the data DTA is at the low level, the pull-up transistors NU1 through NUr included in the pull-up driver 361 may all be turned off according to the pull-up driving signal PUDS. The pull-down driver 363 may receive the pull-down driving signal PDDS corresponding to the pull-down control code PDCD from the pre-driver 330 and may have a resistance determined (e.g., set) by the pull-down control code PDCD.

When the data DTA is at the low level, no current is generated by the pull-up driver 361 and therefore, the data signal DQ that the ODT resistor RODT_MC receives has an output low level (VOL) voltage which is substantially the same as the ground voltage VSS.

According to some example implementations, the total resistance, e.g., a termination resistance (RTT), of the pull-up driver 361 or the pull-down driver 363 may be changed in response to a particular pull-up or pull-down driving signal PUDS or PDDS. Single loading or double loading can be implemented by changing the number of memory modules inserted into a memory slot and an RTT appropriate to conditions can be selected.

FIG. 6 is a diagram for explaining an operation of a data output circuit in FIG. 5 according to some example implementations.

Referring to FIG. 6, the data signal DQ may have a high level or a low level according to the data DTA. The data signal DQ is an alternating current (AC) signal that swings between VOH and an output low level (VOL).

The memory controller 30 may receive the data signal DQ from each of the memory dies 200a-200k, may determine the VOH and VOL voltages, and determine a reference voltage VREF from the VOH and VOL voltages. The memory controller 30 may compare the data signal DQ with the reference voltage VREF and may determine a received data value (e.g., 0 or 1).

Various process-voltage-temperature (PVT) conditions may be applied to each of the memory dies 200a-200k. The PVT conditions may include non-uniform doping in a wafer process, a voltage drop as current passes through different elements when power is supplied, and a temperature along a path through which a signal passes. AC on-resistance (hereinafter, referred to as “Ron AC”) at the output side of the memory dies 200a-200k may vary with the PVT conditions, and the VOH voltage of the data signal DQ may vary with the Ron AC.

Various operating frequencies may be applied to each of the memory dies 200a-200k. When the operating frequency is changed, the VOH voltage of the data signal DQ may vary. Therefore, signal integrity of each of the memory dies 200a-200k may be enhanced by generating the pull-up control code PUCD and the pull-down control code PDCD according to the PVT conditions (e.g., operating parameters) and the operating frequency, such that the data signal DQ has an optimum VOH voltage.

The impedance calibration circuit 400 may generate the pull-up control code PUCD and the pull-down control codes PDCD for various target VOH voltages, in response to the mode register set signal MRS or the impedance calibration command during the impedance calibration interval.

During a normal operation period, the impedance calibration circuit 400 may generate the pull-up control code PUCD and the pull-down control code PDCD for the target VOH voltage associated with the first power supply voltage VDD2L or the second power supply voltage VDD2H, and may provide the pull-up control code PUCD and the pull-down control code PDCD to the data output circuit 360. The data output circuit 360 may transmit the data signal DQ to the memory controller 30 based on the pull-up control code PUCD and the pull-down control code PDCD. The mode register set signal MRS may include information about the impedance of the ODT resistor RODT_MC of the memory controller 30 and may include information indicating whether to increase or decrease the VOH voltage of the data signal DQ. In some example implementations, the mode register set signal MRS may include the impedance calibration command ZQ_CAL.

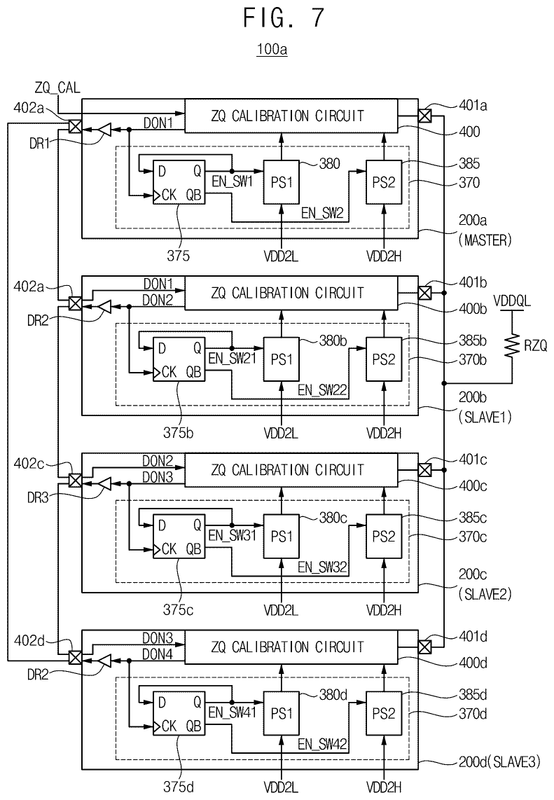

FIG. 7 is a block diagram illustrating an example of the semiconductor memory device in the memory system of FIG. 1 according to some example implementations.

In FIG. 7, assuming that a semiconductor memory device 100a includes memory dies 200a, 200b, 200c and 200d, the memory die 200a is designated as a master die and the memory dies 200b, 200c and 200d are designated as slave dies. The memory dies 200b, 200c and 200d may be referred to as a first slave die, a second slave die and a third slave die, respectively.

Referring to FIG. 7, the master die 200a and the slave dies 200b, 200c and 200d may be commonly connected to the external resistor RZQ connected to the power supply voltage VDDQL through a first impedance pad 401a, a second impedance pad 401b, a third impedance pad 401c and a fourth impedance pad 401d, respectively.

The master die 200a may include the power selection circuit 370, the impedance calibration circuit 400 and the driver DR1. The power selection circuit 370 may include a D-flipflop 375, a first power switch PS1 380 and a second power switch PS2 385.

The D-flipflop 375 may provide a first switch enable signal EN_SW1 to the first power switch 380 and may provide a second switch enable signal EN_SW2 to the second power switch 385 based on the first done signal DON1. The D-flipflop 375 may include a clock terminal CK receiving the first done signal DON1, a first output terminal Q outputting the first switch enable signal EN_SW1, a second output terminal (e.g., an inverted output terminal) QB outputting the second switch enable signal EN_SW2 and an input terminal D connected to the first output terminal Q.

Therefore, the D-flipflop 375 may output (e.g., activate) the first switch enable signal EN_SW1 with a logic high level, may deactivate the first switch enable signal EN_SW1 with a logic low level based on the first done signal DON1 having a logic high level and may active the second switch enable signal EN_SW2 with a logic high level.

The first power switch 380 may provide the first power supply voltage VDD2L to the impedance calibration circuit 400 during the first switch enable signal EN_SW1 being activated with a logic high level and the second power switch 385 may provide the second power supply voltage VDD2H to the impedance calibration circuit 400 during the second switch enable signal EN_SW2 being activated with a logic high level.

The impedance calibration circuit 400 may receive the impedance calibration command ZQ_CAL, may perform a first impedance calibration operation to set the first control code set based on the impedance calibration command ZQ_CAL may transmit the first done signal DON1 to the first slave die 200b through the driver DR1 and the first communication pad 402a when the first control code set is determined (e.g., when the calibration on the first control code set is completed) and may provide the first done signal DON1 to the power selection circuit 370. The first control code set may be based on one of a plurality of power supply voltages.

The first slave die 200b may include a power selection circuit 370b, an impedance calibration circuit 400b and a driver DR2. The power selection circuit 370b may include a D-flipflop 375b, a first power switch 380b and a second power switch 385b.

The D-flipflop 375b may provide a first switch enable signal EN_SW21 to the first power switch 380b and may provide a second switch enable signal EN_SW22 to the second power switch 385b based on a second done signal DON2. The D-flipflop 375b may include a clock terminal CK receiving the second done signal DON2, a first output terminal Q outputting the first switch enable signal EN_SW21, a second output terminal (e.g., an inverted output terminal) QB outputting the second switch enable signal EN_SW22 and an input terminal D connected to the first output terminal Q.

Therefore, the D-flipflop 375b may output (e.g., activate) the first switch enable signal EN_SW21 with a logic high level, may deactivate the first switch enable signal EN_SW21 with a logic low level based on the second done signal DON2 having a logic high level and may active the second switch enable signal EN_SW22 with a logic high level.

The first power switch 380b may provide the first power supply voltage VDD2L to the impedance calibration circuit 400b during the first switch enable signal EN_SW21 being activated with a logic high level and the second power switch 385b may provide the second power supply voltage VDD2H to the impedance calibration circuit 400b during the second switch enable signal EN_SW22 being activated with a logic high level.

The impedance calibration circuit 400b may receive the first done signal DON1, may perform a second impedance calibration operation to set a control code set based on the first done signal DON1, may transmit the second done signal DON2 to the second slave die 200c through the driver DR2 and the second communication pad 402b when the control code set is determined (e.g., when the calibration on the control code set is completed) and may provide the second done signal DON2 to the power selection circuit 370b.

The second slave die 200c may include a power selection circuit 370c, an impedance calibration circuit 400c and a driver DR3. The power selection circuit 370c may include a D-flipflop 375c, a first power switch 380c and a second power switch 385c.

The D-flipflop 375c may provide a first switch enable signal EN_SW31 to the first power switch 380c and may provide a second switch enable signal EN_SW32 to the second power switch 385c based on a third done signal DON3. The D-flipflop 375c may include a clock terminal CK receiving the third done signal DON3, a first output terminal Q outputting the first switch enable signal EN_SW31, a second output terminal (e.g., an inverted output terminal) QB outputting the second switch enable signal EN_SW32 and an input terminal D connected to the first output terminal Q.

Therefore, the D-flipflop 375c may output (e.g., activate) the first switch enable signal EN_SW31 with a logic high level, may deactivate the first switch enable signal EN_SW31 with a logic low level based on the third done signal DON3 having a logic high level and may active the second switch enable signal EN_SW32 with a logic high level.

The first power switch 380c may provide the first power supply voltage VDD2L to the impedance calibration circuit 400c during the first switch enable signal EN_SW31 being activated with a logic high level and the second power switch 385c may provide the second power supply voltage VDD2H to the impedance calibration circuit 400c during the second switch enable signal EN_SW32 being activated with a logic high level.

The impedance calibration circuit 400c may receive the second done signal DON2, may perform a third impedance calibration operation to set a control code set based on the second done signal DON2, may transmit the third done signal DON3 to the third slave die 200d through the driver DR3 and the third communication pad 402c when the control code set is determined (e.g., when the calibration on the control code set is completed) and may provide the third done signal DON3 to the power selection circuit 370c.

The third slave die 200d may include a power selection circuit 370d, an impedance calibration circuit 400d and a driver DR4. The power selection circuit 370d may include a D-flipflop 375d, a first power switch 380d and a second power switch 385d.

The D-flipflop 375d may provide a first switch enable signal EN_SW41 to the first power switch 380d and may provide a second switch enable signal EN_SW42 to the second power switch 385d based on a fourth done signal DON4. The D-flipflop 375d may include a clock terminal CK receiving the fourth done signal DON4, a first output terminal Q outputting the first switch enable signal EN_SW41, a second output terminal (e.g., an inverted output terminal) QB outputting the second switch enable signal EN_SW42 and an input terminal D connected to the first output terminal Q.

Therefore, the D-flipflop 375d may output the first switch (e.g., activate) enable signal EN_SW41 with a logic high level, may deactivate the first switch enable signal EN_SW41 with a logic low level based on the fourth done signal DON4 having a logic high level and may active the second switch enable signal EN_SW42 with a logic high level.

The first power switch 380d may provide the first power supply voltage VDD2L to the impedance calibration circuit 400d during the first switch enable signal EN_SW41 being activated with a logic high level and the second power switch 385d may provide the second power supply voltage VDD2H to the impedance calibration circuit 400d during the second switch enable signal EN_SW42 being activated with a logic high level.

The impedance calibration circuit 400d may receive the third done signal DON4, may perform a fourth impedance calibration operation to set a control code set based on the third done signal DON4, may transmit the fourth done signal DON4 to the master 200a through the driver DR4 and the fourth communication pad 402d when the control code set is determined (e.g., when the calibration on the control code set is completed) and may provide the fourth done signal DON4 to the power selection circuit 370d.

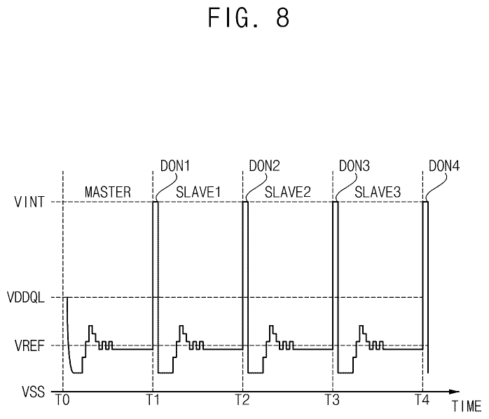

FIG. 8 is a timing diagram illustrating an impedance calibration operation of the semiconductor memory device of FIG. 7 according to some example implementations.

In FIG. 8, assuming that a voltage level of an internal power supply voltage VINT is greater than a voltage level of the power supply voltage VDDQL and the voltage level of the internal power supply voltage VINT is maintained.

Referring to FIGS. 7 and 8, during a time interval between time points T0 and T1, the master die 200a may perform a first impedance calibration operation in response to the impedance calibration command ZQ_CAL, and may transmit, to the first slave die 200b, the first done signal DON1 indicating that the first control code set is determined through the first communication pad 402a.

During a time interval between time points T1 and T2, the first slave die (i.e., SLAVE1) 200b may perform a second impedance calibration operation in response to the first done signal DON1, and may transmit, to the second slave die 200c, the second done signal DON2 indicating that associated control code set is determined (e.g., set) through the second communication pad 402b.

During a time interval between time points T2 and T3, the second slave die (i.e., SLAVE2) 200c may perform a third impedance calibration operation in response to the second done signal DON2, and may transmit, to the third slave die 200d, the third done signal DON3 indicating that associated control code set is determined (e.g., set) through the third communication pad 402c.

During a time interval between time points T3 and T4, the third slave die (i.e., SLAVE2) 200d may perform a fourth impedance calibration operation in response to the third done signal DON3, and may transmit, to the master die 200a, the fourth done signal DON4 indicating that associated control code set is determined (e.g., set) through the fourth communication pad 402d.

In FIG. 8, in each of time intervals T0-T1, T1-T2, T2-T3 and T3-T4, a voltage swinging between the power supply voltage VDDQL and a ground voltage VSS with respect to a reference voltage VREF indicates that an impedance of the output driver 360 converges to a voltage level of the reference voltage VREF by each of the impedance calibration circuits 400, 400b, 400c and 400d performing a corresponding impedance calibration operation.

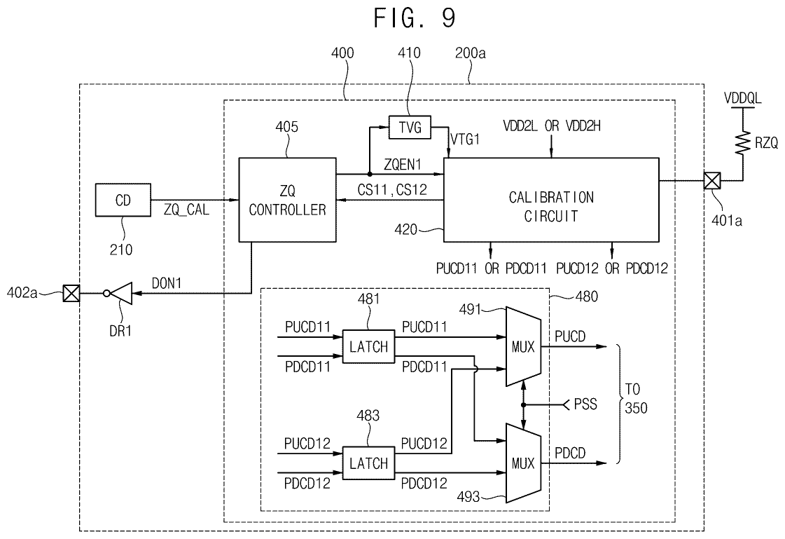

FIG. 9 illustrates a block diagram illustrating an impedance calibration circuit in the master die in FIG. 7 according to some example implementations.

Referring to FIG. 9, the impedance calibration circuit 400 may include a calibration (ZQ) controller 405, a calibration circuit 420, a target voltage generator TVG 410 and a code selection circuit 480.

The calibration controller 405 may receive the impedance calibration command ZQ_CAL from the command decoder (i.e., a corresponding command decoder) CD 210 in the master die 200a.

The calibration circuit 420 may be connected to the external resistor RZQ through the first impedance pad 401a, may perform the first impedance calibration operation in response to a calibration enable signal ZQEN1 from the calibration controller 405, may provide the code selection circuit 480 with a first control code set including a first pull-up control code PUCD11 and a first pull-down control code PDCD11 based on the first power supply voltage VDD2L or a second control code set including a second pull-up control code PUCD12 and a second pull-down control code PDCD12 based on the second power supply voltage VDD2H, and may provide the calibration controller 405 with a first comparison signal CS11 and a second comparison signal CS12 indicating that the first impedance calibration operation is completed.

The target voltage generator 410 may generate a first target VOH voltage VTG1 in response to the calibration enable signal ZQEN1 and may provide the first target VOH voltage VTG1 to the calibration circuit 420.

The calibration controller 405 may transmit, to the first slave die 200b, the first done signal DON1 through the driver DR1 and the first communication pad 402a based on the first comparison signal CS11 and the second comparison signal CS12 indicating that the first impedance calibration operation is completed.

The code selection circuit 480 may latch the first control code set including the first pull-up control code PUCD11 and the first pull-down control code PDCD11 and the second control code set including the second pull-up control code PUCD12 and the second pull-down control code PDCD12, and may output one of the latched first control code set and the latched second control code set to the pre-driver 350 in FIG. 4 as a target control code set. The target control code set may include a pull-up control code PUCD and a pull-down control code PDCD.

The code selection circuit 480 may include a first latch 481, a second latch 483, a first multiplexer 491 and a second multiplexer 493.

The first latch 481 may latch the first control code set including the first pull-up control code PUCD11 and the first pull-down control code PDCD11 based on the first power supply voltage VDD2L and may provide the first pull-up control code PUCD11 and the first pull-down control code PDCD11 to the first multiplexer 491 and the second multiplexer 493, respectively. The second latch 483 may the second pull-up control code PUCD12 and the second pull-down control code PDCD12 based on the second power supply voltage VDD2H and may provide the second pull-up control code PUCD12 and the second pull-down control code PDCD12 to the first multiplexer 491 and the second multiplexer 493, respectively.

The first multiplexer 491 may output one of the first pull-up control code PUCD11 and the second pull-up control code PUCD12 as the pull-up control code PUCD, based on the power selection signal PSS and the second multiplexer 493 may output one of the first pull-down control code PDCD11 and the second pull-down control code PDCD12 as the pull-down control code PDCD, based on the power selection signal PSS.

In some example implementations, the code selection circuit 480 may be disposed at an outside of the impedance calibration circuit 400 instead of being included in the impedance calibration circuit 400.

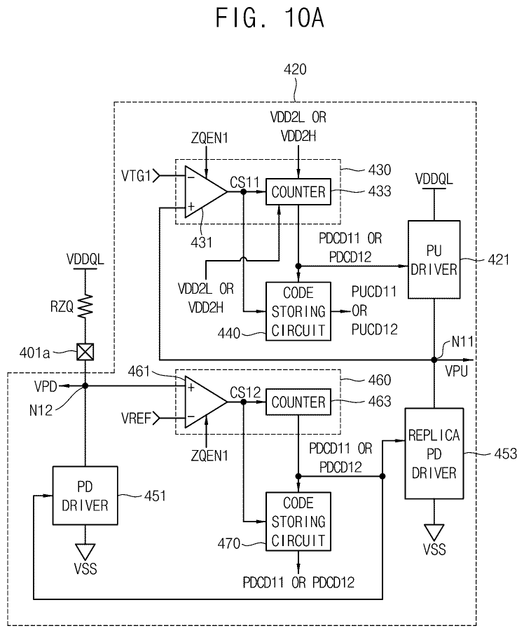

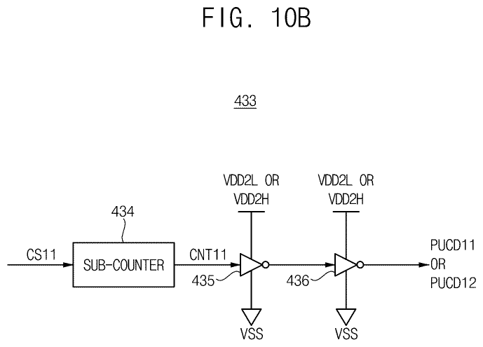

FIG. 10A is a block diagram illustrating an example of a calibration circuit in the impedance calibration circuit of FIG. 9 according to some example implementations.

Referring to FIG. 10A, the calibration circuit 420 may include a pull-up PU driver 421, a first code generator 430, a first code storing circuit 440, a pull-down PD driver 451, a replica pull-down PD driver 453, a second code generator 460, and a second code storing circuit 470.

The pull-up driver 421 may be connected between the power supply voltage VDDQL and a first node N11, and may have a configuration similar to the pull-up driver 361 in FIG. 5. The replica pull-down driver 453 may be connected between the first node N11 and the ground voltage VSS, and may have a configuration similar to the pull-down driver 363 in FIG. 5. The pull-down driver 451 may be connected between a second node N12 and the ground voltage VSS, and the second node N12 may be coupled to the first impedance pad 401a connected to the external resistor RZQ. The external resistor RZQ may be connected to the power supply voltage VDDQL. The pull-down driver 451 may have a configuration similar to the pull-down driver 363 in FIG. 5.

The first code generator 430 may generate the first pull-up control code PUCD11 or the second pull-up control code PUCD12 obtained by comparing the first target VOH voltage VTG1 with a first voltage (or a pull-up voltage) VPU of the first node N11. The first code generator 430 may include a first comparator 431 and a first counter 433.

The first comparator 431 may be enabled in response to the calibration enable signal ZQEN1, may compare the first target VOH voltage VTG1 with the first voltage VPU to output the first comparison signal CS11, and may provide the first comparison signal CS11 to the first counter 433 and the first code storing circuit 440. The first counter 433 may operate based on the first power supply voltage VDD2L or the second power supply voltage VDD2H, may perform a counting operation in response to the first comparison signal CS11 to generate the first pull-up control code PUCD11 or the second pull-up control code PUCD12 and may perform a counting operation to increase or decrease the first pull-up control code PUCD11 or the second pull-up control code PUCD12 until a logic level of the first comparison signal CS11 transits. The first counter 433 may provide the first pull-up control code PUCD11 or the second pull-up control code PUCD12 to the pull-up driver 421 and the first code storing circuit 440.

The pull-up driver 421 may adjust/calibrate a pull-up impedance in response to the first pull-up control code PUCD11 or the second pull-up control code PUCD12. The first pull-up control code PUCD11 or the second pull-up control code PUCD12 may be calibrated and/or changed until the first target VOH voltage VTG1 becomes substantially same as the first voltage VPU.

The first code storing circuit 440 may store the first pull-up control code PUCD11 or the second pull-up control code PUCD12 when the logic level of the first comparison signal CS11 transits. In other words, the first code storing circuit 440 may store the first pull-up control code PUCD11 or the second pull-up control code PUCD12 when the first target VOH voltage VTG1 becomes same as the first voltage VPU.

The second code generator 460 may generate the first pull-down control code PDCD11 or the second pull-down control code PDCD12 obtained by comparing a second voltage (or a pull-down voltage) VPD of the second node N12 with the reference voltage VREF. The second code generator 460 may include a second comparator 461 and a second counter 463. The second comparator 461 may be enabled in response to the calibration enable signal ZQEN1, may compare the reference voltage VREF with the second voltage VPD to output the second comparison signal CS12 and may provide the second comparison signal CS12 to the second counter 463 and the second code storing circuit 470.

Although not illustrated, the second counter 463 may operate based on the first power supply voltage VDD2L or the second power supply voltage VDD2H, may perform a counting operation in response to the second comparison signal CS12 to generate the first pull-down control code PDCD11 or the second pull-down control code PDCD12 and may perform a counting operation to increase or decrease the first pull-down control code PDCD11 or the second pull-down control code PDCD12 until a logic level of the second comparison signal CS2 transits. The second counter 463 may provide the first pull-down control code PDCD11 or the second pull-down control code PDCD12 to the pull-down driver 451, the replica pull-down driver 453, and the second code storing circuit 470.

The pull-down driver 451 may adjust/calibrate a pull-down impedance in response to the first pull-down control code PDCD11 or the second pull-down control code PDCD12. The replica pull-down driver 453 may adjust/calibrate a pull-down impedance in response to the first pull-down control code PDCD11 or the second pull-down control code PDCD12. The first pull-down control code PDCD11 or the second pull-down control code PDCD12 may be calibrated and/or changed until the second voltage VPD becomes substantially the same as the reference voltage VREF. The second code storing circuit 470 may store the first pull-down control code PDCD11 or the second pull-down control code PDCD12 when the logic level of the second comparison signal CS12 transits. In other words, the second code storing circuit 470 may store the first pull-down control code PDCD11 or the second pull-down control code PDCD12 when the second voltage VPD becomes same as the reference voltage VREF.

The calibration circuit 420 provides the first comparison signal CS11 and the second comparison signal CS12 to the calibration controller 405 in FIG. 9.

FIG. 10B is a block diagram illustrating an example of the first counter in FIG. 10A according to some example implementations.

Referring to FIG. 10B, the first counter 433 may include a sub-counter 434, a first inverter 435 and a second inverter 436.

The sub-counter 434 may generate a counted value CNT by counting the first comparison signal CS11. The first inverter 435 may be connected between the first power supply voltage VDD2L and the ground voltage VSS or between the second power supply voltage VDD2H and the ground voltage VSS and may invert the counted value CNT. The second inverter 436 may be connected between the first power supply voltage VDD2L and the ground voltage VSS or between the second power supply voltage VDD2H and the ground voltage VSS and may output the first pull-up control code PUCD11 or the second pull-up control code PUCD12 by inverting an output of the first inverter 435.

When the first inverter 435 and the second inverter 436 are connected to the first power supply voltage VDD2L, at least one of bits having a logic high level, of the first pull-up control code PUCD11 may have a voltage level of the first power supply voltage VDD2L. When the first inverter 435 and the second inverter 436 are connected to the second power supply voltage VDD2H, at least one of bits having a logic high level, of the second pull-up control code PUCD12 may have a voltage level of the second power supply voltage VDD2H.

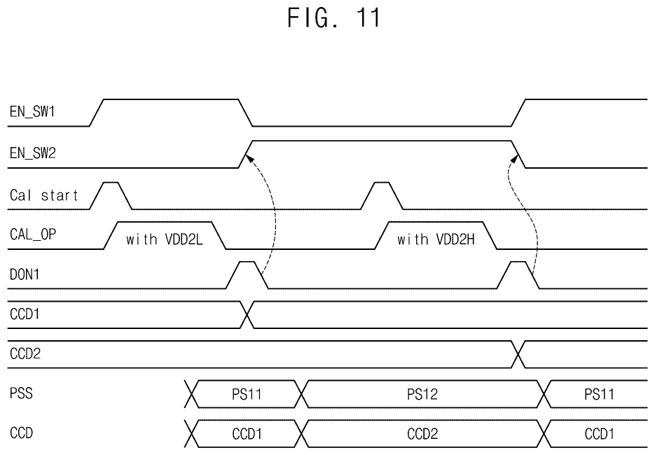

FIG. 11 is a timing diagram illustrating an example operation of the impedance calibration circuit in FIGS. 7 and 9 according to some example implementations.

Referring to FIGS. 7, 9 and 11, when an impedance calibration starts (Cal start), a first switch enable signal EN_SW1 is activated, the first power switch 380 provides the first power supply voltage VDD2L to the impedance calibration circuit 400 during the first switch enable signal EN_SW1 being activated. The impedance calibration circuit 400 performs an impedance calibration operation CAL_OP to set a first control code set CCD1 associated with the first power supply voltage VDD2L, provides the first control code set CCD1 to the code selection circuit 480 and transits the first done signal DON1 to a logic high level. The first switch enable signal EN_SW1 may correspond to the first switch enable signal EN_SW11.

Based on the first done signal DON1 transitioning to a logic high level, the second switch enable signal EN_SW2 is activated, the second power switch 385 provides the second power supply voltage VDD2H to the impedance calibration circuit 400 during the second switch enable signal EN_SW2 being activated. The impedance calibration circuit 400 performs an impedance calibration operation CAL_OP to set a second control code set CCD2 associated with the second power supply voltage VDD2H, provides the second control code set CCD2 to the code selection circuit 480 and transits the first done signal DON1 to a logic high level. The second switch enable signal EN_SW2 may correspond to the second switch enable signal EN_SW12.

When the first power switch PS11 is enabled based on the power selection signal PSS, the first control code set CCD1 latched in the code selection circuit 480 may be provided to the pre-driver 350 in FIG. 4 as the target control code set CCD. When the second power switch PS12 is enabled based on the power selection signal PSS, the second control code set CCD2 latched in the code selection circuit 480 may be provided to the pre-driver 350 in FIG. 4 as the target control code set CCD.

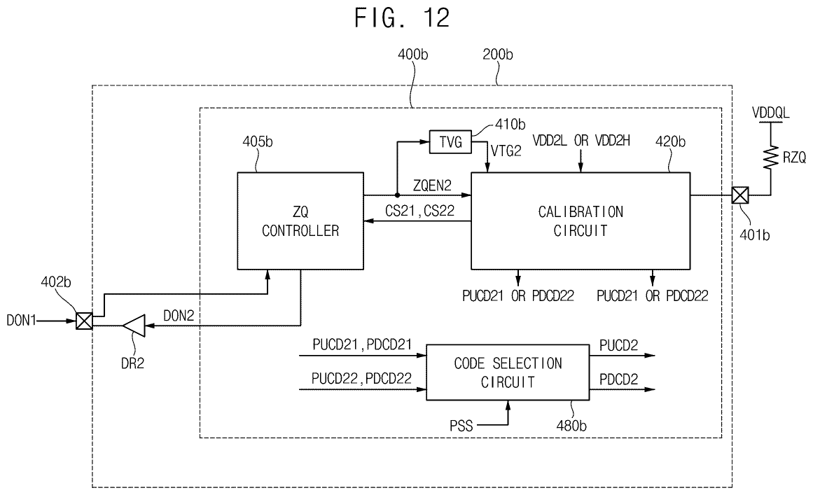

FIG. 12 is a block diagram illustrating an impedance calibration circuit in the first slave die in FIG. 7 according to example implementations.

Referring to FIG. 12, the first slave die 200b may include the driver DR2 and the impedance calibration circuit 400b. The impedance calibration circuit 400b may be connected to the second impedance pad 401b and the second communication pad 402b and may include a calibration (ZQ) controller 405b, a calibration circuit 420b, a target voltage generator 410b and a code selection circuit 480b.

The calibration controller 405b may activate a calibration enable signal ZQEN2 based on the first done signal DON1 received through the second communication pad 402b and may maintain an activated state of the calibration enable signal ZQEN2 during an impedance calibration interval.

The calibration circuit 420b may be connected to the external resistor RZQ through the second impedance pad 401b, may perform a second impedance calibration operation in response to the calibration enable signal ZQEN2 from the calibration controller 405b, may provide the code selection circuit 480b with a third control code set including a first pull-up control code PUCD21 and a first pull-down control code PDCD21 based on the first power supply voltage VDD2L or a fourth control code set including a second pull-up control code PUCD22 and a second pull-down control code PDCD22 based on the second power supply voltage VDD2H, and may provide the calibration controller 405b with a first comparison signal CS21 and a second comparison signal CS22 indicating that the second impedance calibration operation is completed.

The target voltage generator 410b may generates a second target VOH voltage VTG2 in response to the calibration enable signal ZQEN2 and may provide the second target VOH voltage VTG2 to the calibration circuit 420b.

The calibration controller 405b may transmit, to the second slave die 200c, the second done signal DON2 through the driver DR2 and the second communication pad 402b based on the first comparison signal CS21 and the second comparison signal CS22 indicating that the second impedance calibration operation is completed.

The code selection circuit 480b may latch the third control code set including the first pull-up control code PUCD21 and the first pull-down control code PDCD21 and the fourth control code set including the second pull-up control code PUCD22 and the second pull-down control code PDCD22, and may output one of the latched third control code set and the latched fourth control code set to a corresponding pre-driver as a target control code set. The target control code set may include a pull-up control code PUCD2 and a pull-down control code PDCD2.

A configuration of the code selection circuit 480b may be substantially the same as or similar with a configuration of the code selection circuit 480 in FIG. 9.

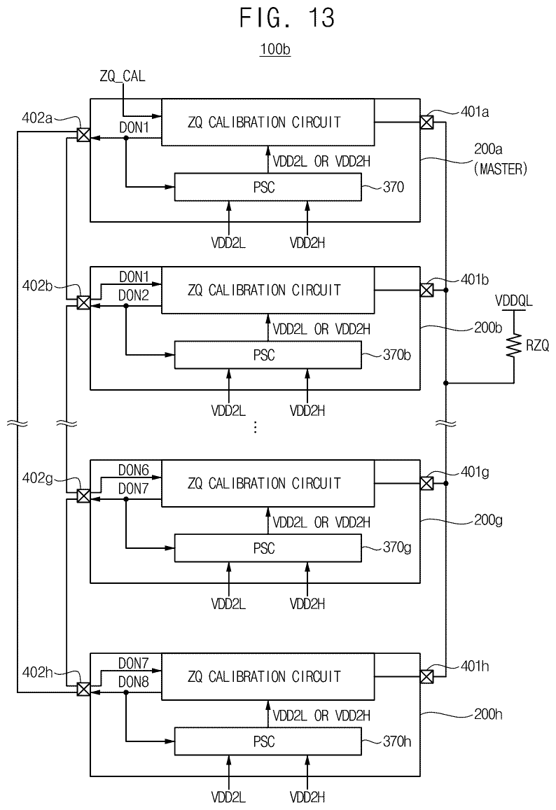

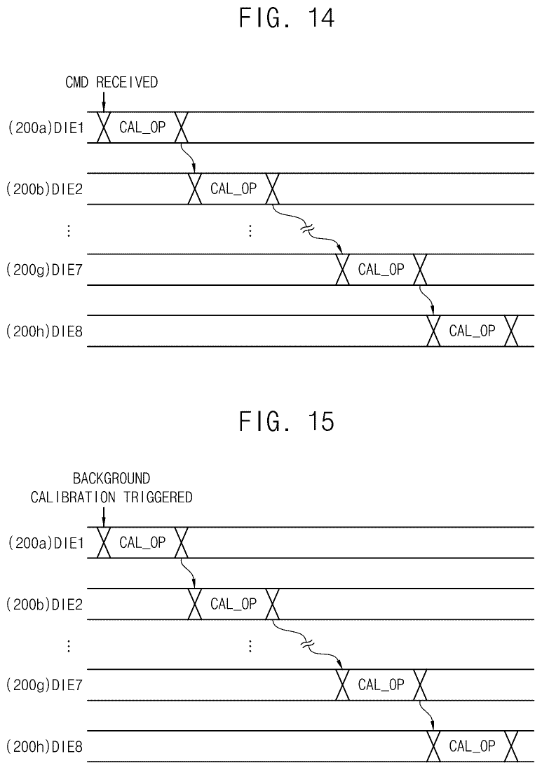

FIGS. 13 and 14 illustrate that the impedance calibration operation is performed in the semiconductor memory device in FIG. 1, according to some example implementations.

In FIG. 13, assuming that the semiconductor memory device 100 in FIG. 1 is implemented with a semiconductor memory device 100b that includes the master die 200a and slave dies 200b, . . . , 200g and 200h. Here, h is an integer greater than two.

Referring to FIG. 13, each of the master die 200a and the slave dies 200b, . . . , 200g and 200h includes respective one of impedance pads 401a, 401b, . . . , 401g and 401h connected to the external resistor RZQ, and may include respective one of communication pads 402a, 402b, . . . , 402g and 402h which are connected in a daisy-chain configuration.

The master die 200a may include the power selection circuit PSC 370 and the impedance calibration circuit 400, the slave die 200b may include the power selection circuit 370b and the impedance calibration circuit 400b, the slave die 200g may include a power selection circuit 370g and an impedance calibration circuit 400g and the slave die 200h may include a power selection circuit 370h and an impedance calibration circuit 400h. In FIG. 13, a driver included in each of the master die 200a and the slave dies 200b, . . . , 200g and 200h is not illustrated for convenience of explanation.

Referring to FIG. 14, the master die 200 (e.g., DIE1) may receive the impedance calibration command ZQ_CAL from the memory controller 30 during an initialization sequence, may perform an impedance calibration operation CAL_OP, and may transmit, to the slave die 200b (e.g., DIE2), the first done signal DON1 indicating completion of the impedance calibration operation CAL_OP through the communication pad 402a. The completion of the impedance calibration operation CAL_OP may refer to a completion of calibrating the first control code set associated with the first power supply voltage or a completion of calibrating he first control code set associated with the second power supply voltage in FIG. 14.

The impedance calibration circuit 400b in the slave die 200b may perform an impedance calibration operation CAL_OP based on the first done signal DON1 and may transmit, to an adjacent slave die, the second done signal DON2 indicating completion of the impedance calibration operation CAL_OP through the communication pad 402b.

The impedance calibration circuit 400g in the slave die 200g (e.g., DIE7) may perform an impedance calibration operation CAL_OP based on the done signal received from an adjacent slave die and may transmit, to an adjacent slave die 200h (e.g., DIE8), a done signal DON7 indicating completion of the impedance calibration operation CAL_OP through the communication pad 402g.

The impedance calibration circuit 400h in the slave die 200h (e.g., DIE8) may perform an impedance calibration operation CAL_OP based on the done signal DON7 and may transmit, to the master die 200a, a done signal DON8 indicating completion of the impedance calibration operation CAL_OP through the communication pad 402h.

FIG. 15 illustrates that a background impedance calibration operation is performed during an idle period in the semiconductor memory device in FIG. 13, according to some example implementations.

Referring to FIG. 15, the master die 200a activates the calibration enable signal ZQEN1 internally based on setting of the mode register 212, may perform a background impedance calibration operation CAL_OP, and may transmit, to the slave die 200b, the first done signal DON1 indicating completion of the impedance calibration operation CAL_OP through the communication pad 402a. The completion of the impedance calibration operation CAL_OP may refer to a completion of calibrating the first control code set associated with the first power supply voltage or a completion of calibrating the first control code set associated with the second power supply voltage in FIG. 14.

The impedance calibration circuit 400b in the slave die 200b may perform a background impedance calibration operation CAL_OP based on the first done signal DON1 and may transmit, to an adjacent slave die, the second done signal DON2 indicating completion of the background impedance calibration operation CAL_OP through the communication pad 402b.

The impedance calibration circuit 400g in the slave die 200g (e.g., DIE7) may perform a background impedance calibration operation CAL_OP based on the done signal received from an adjacent slave die and may transmit, to an adjacent slave die 200h (e.g., DIE8), a done signal DON7 indicating completion of the background impedance calibration operation CAL_OP through the communication pad 402g.

The impedance calibration circuit 400h in the slave die 200h (e.g., DIE8) may perform a background impedance calibration operation CAL_OP based on the done signal DON7 and may transmit, to the master die 200a, a done signal DON8 indicating completion of the background impedance calibration operation CAL_OP through the communication pad 402h.

Each of the master die 200 a and the slave dies 200b, . . . , 200g and 200h may perform the background impedance calibration operation periodically.

As described with reference to FIGS. 1 and 15, the master die 200a and the slave dies 200b, . . . , 200g and 200h may be provided (formed) in the same board 110, may be commonly connected to the external resistor RZQ through respective one of impedance pads and may perform the impedance calibration operation sequentially by communicating with each other through the communication pads. Therefore, when the data I/O circuit operates based on at least two different power supply voltages, the semiconductor memory device 100 may enhance performance because each of the master die 200a and the slave dies 200b, . . . , 200g and 200h sets control code sets associated with the different power supply voltages in advance during an impedance calibration interval, latches the control code sets therein and selects corresponding one of the control code sets based on a provided power supply voltage without additional calibration time interval when a power domain is changed.

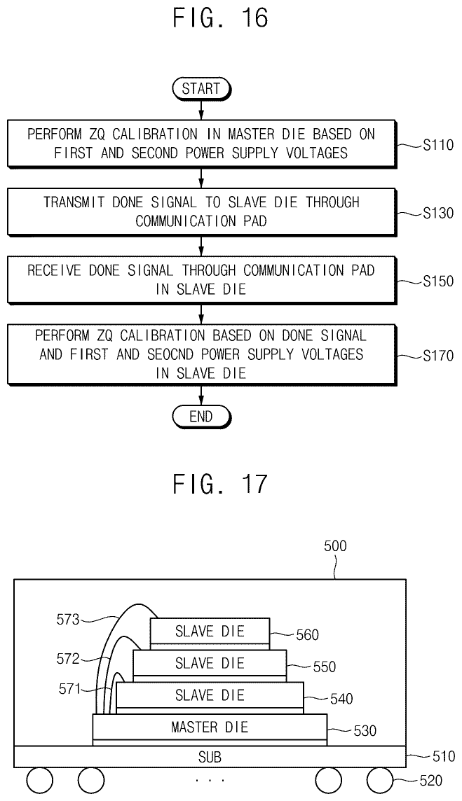

FIG. 16 is a flowchart illustrating a method of operating a semiconductor memory device including multi-dies according to some example implementations.

Referring to FIGS. 1 through 16, there is provided a method of operating the semiconductor memory device 100 including the master die 200a and the plurality of slave dies 200b-200k which are commonly connected to the external resistor RZQ in the board 110. According to the method, the master die 200a performs a first impedance calibration operation to set a first control code set associated with a first power supply voltage or a second control code set associated with a second power supply voltage (operation S110) and transmits a done signal indicating that the first control code set or the second control code set is set (e.g., determined) to a second slave die 200b among the plurality of slave dies 200b-200k through a communication pad (operation S130).

The second slave die 200b receives the done signal through a corresponding communication pd (operation S150), performs a second impedance calibration operation to set a third control code set associated with the first power supply voltage or a fourth control code set associated with the second power supply voltage (operation S170), and transmits a done signal indicating that the third control code set or the fourth control code set is set (e.g., determined) to a slave die adjacent to the second slave die 200b through a communication pad

FIG. 17 is a schematic diagram of a multi-chip package including a semiconductor memory device according to some example implementations.

Referring to FIG. 17, a multi-chip package 500 may include a plurality of memory dies 530, 540, 550 and 560 which are sequentially stacked on a package substrate 510. The memory die 530 may be a master die and the memory dies 540, 550 and 560 may be slave dies. The master die 530 may have substantially the same configuration of the master die 200a in FIG. 7 and each of the slave dies 540, 550 and 560 may have substantially similar configuration of the master die 200a in FIG. 7.

A through-silicon via (TSV) (not shown), a bonding wire (not shown), a bump (not shown), or a solder ball 520 may be used to electrically connect the memory dies 530, 540, 550 and 560 with one other.

Each of the memory dies 530, 540, 550 and 560 may employ an impedance calibration circuit. The master die 530 may employ the pose selection circuit 370 and the impedance calibration circuit 400 in FIG. 7 and each of the slave dies 540, 550 and 560 may employ the power selection circuit 370b the impedance calibration circuit 400b in FIG. 7.

The master die 530 may be connected to the slave die 540 through a wire 571, may be connected to the slave die 550 through a wire 572 and may be connected to the slave die 560 through a wire 573.

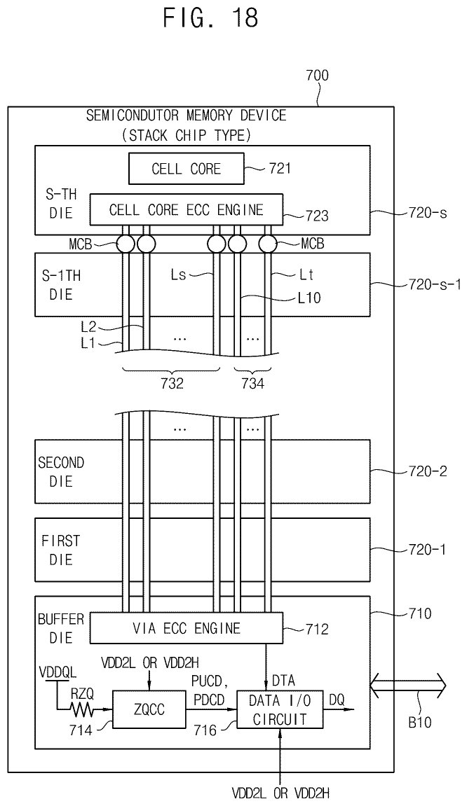

FIG. 18 is a block diagram illustrating a semiconductor memory device according to some example implementations.

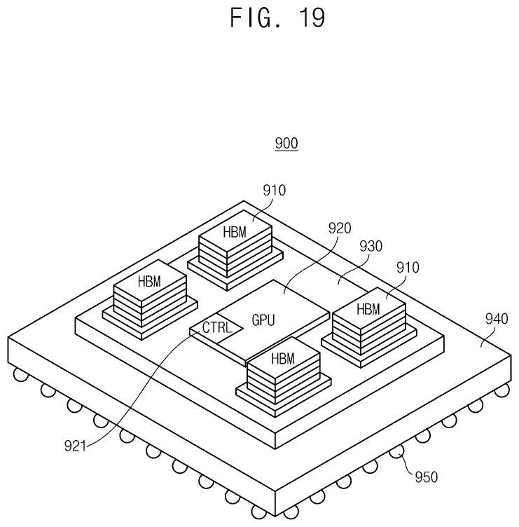

Referring to FIG. 19, a semiconductor memory device 700 may include at least one buffer die 710 and a plurality of memory dies 720-1,720-2, . . . ,720-s (s is a natural number equal to or greater than three) providing a soft error analyzing and correcting function in a stacked chip structure.

The plurality of memory dies 720-1,720-2, . . . ,720-s may be stacked on the buffer die 710, and may convey data through a plurality of through silicon via (TSV) lines.

Each of the memory dies 720-1,720-2, . . . ,720-s may include cell core 721 to store data and a cell core error correction code (ECC) engine 722 to generate transmission parity bits (e.g., transmission parity data) based on transmission data to be sent to the at least one buffer die 710. The cell core 721 may include a plurality of memory cells having DRAM cell structure.

The buffer die 710 may include a via ECC engine 712, which may correct a transmission error using the transmission parity bits when a transmission error is detected from the transmission data received through the TSV lines, and generate error-corrected data.

The buffer die 710 may further include an impedance calibration circuit ZQCC 714 and a data I/O circuit 716. The impedance calibration circuit 714 may be connected to an external resistor RZQ coupled to the power supply voltage VDDQL.

The impedance calibration circuit 714 may employ the impedance calibration circuit 400 in FIG. 9. The impedance calibration circuit 714 may provide the data I/O circuit 716 with a first control code set including a first pull-up control code and a first pull-down control code associated with the first power supply voltage VDD2L or a second control code set including a second pull-up control code and a second pull-down control code associated with the second power supply voltage VDD2H as a target control code set including a pull-up control code PUCD and a pull-down control code PDCD. The data I/O circuit 716 may receive the first power supply voltage VDD2L or the second power supply voltage VDD2H and may drive a data DTA provided from the via ECC engine 712 based on the pull-up control code PUCD and the pull-down control code PDCD to transmit a data signal DQ having a target VOH voltage to an external memory controller (for example, the memory controller 30).

The semiconductor memory device 700 may be, e.g., a stack chip type memory device or a stacked memory device that conveys data and control signals through the TSV lines. The TSV lines may be also called ‘through electrodes’.

The cell core ECC engine 722 may perform error correction on data that is output from the memory die 720-s before the transmission data is sent.

A transmission error that occurs at the transmission data may be due to, e.g., noise that occurs at the TSV lines. Since data fail due to the noise occurring at the TSV lines may be distinguishable from data fail due to a false operation of the memory die, it may be regarded as soft data fail (or a soft error). The soft data fail may be generated due to transmission fail on a transmission path, and may be detected and remedied by an ECC operation.

A data TSV line group 732, which is formed at one memory die 720-p, may include TSV lines L1, L2 to Lt, and a parity TSV line group 734 may include TSV lines L10 to Ls.

The TSV lines L1, L2 to Lt of the data TSV line group 732 and the parity TSV lines L10 to Ls of the parity TSV line group 734 may be connected to micro bumps MCB, which are correspondingly formed among the memory dies 720-1 to 720-s.

The semiconductor memory device 700 may have a three-dimensional (3D) chip structure or a 2.5D chip structure to communicate with the host through a data bus B10. The buffer die 710 may be connected with the external memory controller through the data bus B10.

The cell core ECC engine 722 may output transmission parity bits as well as the transmission data through the parity TSV line group 734 and the data TSV line group 732 respectively. The output transmission data may be data that is error-corrected by the cell core ECC engine 722.

The via ECC engine 712 may determine whether a transmission error occurs at the transmission data received through the data TSV line group 732, based on the transmission parity bits received through the parity TSV line group 734. When a transmission error is detected, the via ECC engine 712 may correct the transmission error on the transmission data using the transmission parity bits. When the transmission error is uncorrectable, the via ECC engine 712 may output information indicating occurrence of an uncorrectable data error. When an error is detected from read data in a high bandwidth memory (HBM) or the stacked memory structure, the error may be an error occurring due to noise while data is transmitted through the TSV.

According to example implementations, as illustrated in FIG. 18, the cell core ECC engine 722 may be included in the memory die 720-s, and the via ECC engine 712 may be included in the buffer die 710. Accordingly, it may be possible to detect and correct soft data fail. The soft data fail may include a transmission error that is generated due to noise when data is transmitted through TSV lines.

FIG. 19 is a configuration diagram illustrating a semiconductor package including the stacked memory device according to example implementations.

Referring to FIG. 19, a semiconductor package 900 may include one or more stacked memory devices 910 and a graphic processing unit (GPU) 920.

The stacked memory devices 910 and the GPU 920 may be mounted on an interposer 930, and the interposer on which the stacked memory device 910 and the GPU 920 are mounted may be mounted on a package substrate 940 mounted on solder balls 950. The GPU 920 may correspond to a semiconductor device which may perform a memory control function, and for example, the GPU 920 may be implemented as an application processor. The GPU 920 may include a memory controller CTRL 921.

The stacked memory device 910 may be implemented in various forms, and the stacked memory device 910 may be a memory device in a high bandwidth memory (HBM) form in which a plurality of layers are stacked. Accordingly, the stacked memory device 910 may include a buffer die and a plurality of memory dies, each of the plurality of memory dies include a cell core and a cell core ECC engine and the buffer die may include an impedance calibration circuit.

The plurality of stacked memory devices 910 may be mounted on the interposer 930, and the GPU 920 may communicate with the plurality of stacked memory devices 910. For example, each of the stacked memory devices 910 and the GPU 920 may include a physical region, and communication may be performed between the stacked memory devices 910 and the GPU 920 through the physical regions. Meanwhile, when the stacked memory device 910 includes a direct access region, a test signal may be provided into the stacked memory device 910 through conductive means (e.g., solder balls 950) mounted under package substrate 940 and the direct access region.

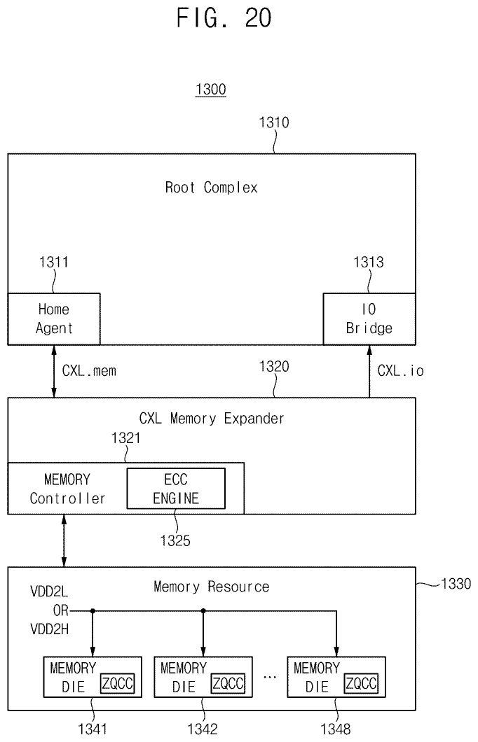

FIG. 20 is an example of a computing system when a memory system according to example implementations corresponds to a Type 3 memory system defined by a compute express link (CXL) protocol.

Referring to FIG. 20, a computing system 1300 may include a root complex 1310, a CXL memory expander 1320 connected to the root complex 1310 and a memory resource 1330. The memory resource 1330 may correspond to the semiconductor memory device 100 in FIG. 1.

The root complex 1310 may include a home agent 1311 and an I/O bridge 1313, and the home agent 1311 may communicate with the CXL memory expander 1320 based on a coherent protocol CXL. mem the I/O bridge 1313 may communicate with the CXL memory expander 1320 based on a non-coherent protocol, i.e., an I/O protocol CXL.io. In a CXL protocol base, the home agent 1311 may correspond to an agent on a host side that is arranged to solve the entire consistency of the computing system 1300 for a given address.

The CXL memory expander 1320 may include a memory controller 1321, the memory controller 1321 may employ the memory controller 30 in FIG. 1, and the memory controller 1321 may include the ECC engine 1325.

In addition, the CXL memory expander 1320 may output data to the root complex 1310 via the I/O bridge 1313 based on the I/O protocol CXL.io or the PCIe.

The memory resource 1330 may include a plurality of memory dies 1341, 1342, . . . , 1348 that is designated as a master die 1341 and slave dies 1342, . . . , 1348. The master die 1341 and the slave dies 1342, . . . , 1348 may operate based on the first power supply voltage VDD2L or the second power supply voltage VDD2H. Each of the master die 1341 and the slave dies 1342, . . . , 1348 may include an impedance calibration circuit ZQCC corresponding to the impedance calibration circuit 400a or the impedance calibration circuit 400b. The master die 1341 and the slave dies 1342, . . . , 1348 may be commonly connected to the external resistor RZQ through respective one of impedance pads and may perform the impedance calibration operation sequentially by communicating with each other through respective one of communication pads. Therefore, the master die 1341 and the slave dies 1342, . . . , 1348 may enhance performance because each of the master die 1341 and the slave dies 1342, . . . , 1348 sets control code sets associated with the different power supply voltages in advance during an impedance calibration interval, latches the control code sets therein and selects corresponding one of the control code sets based on a provided power supply voltage without additional calibration time interval when a power domain is changed.

Example implementations may be applied to systems using semiconductor memory devices that include multi-dies. For example, implementations may be applied to systems such as be a smart phone, a navigation system, a notebook computer, a desk top computer, and a game console that use the semiconductor memory device as a working memory.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
an external resistor in a board; and
a plurality of memory dies on the board, being connected to the external resistor, the plurality of memory dies including a master die and a plurality of slave dies,
wherein the master die includes a first output driver and a first communication pad, and the master die is configured to, during an impedance calibration interval:
determine, based on a first power supply voltage, a first control code set associated with the first output driver;
latch the first control code set;
generate a first done signal indicating that the first control code set is determined;
transmit the first done signal to a first slave die of the plurality of slave dies through the first communication pad;
based on the first done signal, determine, based on a second power supply voltage, a second control code set associated with the first output driver; and
latch the second control code set, and
wherein the first slave die includes a second output driver and a second communication pad, and the first slave die is configured to:
receive, from the master die, the first done signal through the second communication pad;
based on the first done signal, determine, based on the first power supply voltage, a third control code set associated with the second output driver;
latch the third control code set;
generate a second done signal indicating that the third control code set is determined;
based on the second done signal, determine, based on the second power supply voltage, a fourth control code set associated with the second output driver; and
latch the fourth control code set.

2. The semiconductor memory device of claim 1, wherein the master die is configured to perform a first impedance calibration operation to determine the first control code set or the second control code set in response to an impedance calibration command received from an external device.

3. The semiconductor memory device of claim 1, wherein the master die is configured to perform a first impedance calibration operation to determine the first control code set or the second control code set periodically based on a mode register set signal generated in the master die.

4. The semiconductor memory device of claim 1, wherein the master die includes:
an impedance calibration circuit connected to the external resistor through a first impedance pad; and
a power selection circuit configured to receive the first power supply voltage and the second power supply voltage, provide the first power supply voltage to the impedance calibration circuit, and provide, based on the first done signal, the second power supply voltage to the impedance calibration circuit.

5. The semiconductor memory device of claim 4, wherein the power selection circuit includes:
a first power switch configured to provide the first power supply voltage to the impedance calibration circuit based on a first switch enable signal;
a second power switch configured to provide the second power supply voltage to the impedance calibration circuit based on a second switch enable signal; and
a D-flipflop that includes
a clock terminal configured to receive the first done signal,
a first output terminal configured to output the first switch enable signal,
a second output terminal configured to output the second switch enable signal, and
an input terminal connected to the first output terminal.

6. The semiconductor memory device of claim 5, wherein the D-flipflop is configured to:
activate the first switch enable signal with a logic high level;
deactivate the first switch enable signal with a logic low level based on the first done signal having a logic high level; and
activate the second switch enable signal with a logic high level.

7. The semiconductor memory device of claim 4, wherein the impedance calibration circuit includes:
a calibration controller configured to receive an impedance calibration command from a command decoder;
a calibration circuit connected to the external resistor through a first impedance pad; and
a code selection circuit,
wherein the calibration circuit is configured to:
perform a first impedance calibration operation to determine the first control code set or the second control code set based on a calibration enable signal from the calibration controller; and
provide the calibration controller with a first comparison signal and a second comparison signal indicating that the first impedance calibration operation is completed,
wherein the code selection circuit is configured to:
latch the first control code set based on the first power supply voltage being provided to the calibration circuit;
latch the second control code set based on the second power supply voltage being provided to the calibration circuit; and
based on a power selection signal, provide, as a target control code set, the first output driver with one of the latched first control code set and the latched second control code set, and
wherein the calibration controller is configured to transmit, based on the first comparison signal and the second comparison signal, the first done signal to the first slave die through the first communication pad.

8. The semiconductor memory device of claim 7, wherein the code selection circuit includes:
a first latch configured to latch the first control code set;
a second latch configured to latch the second control code set;
a first multiplex configured to, in response to the power selection signal, output one of a first pull-up control code of the first control code set and a second pull-up control code of the second control code set as a pull-up control code of the target control code set; and
a second multiplex configured to, in response to the power selection signal, output one of a first pull-down control code of the first control code set and a second pull-down control code of the second control code set as a pull-down control code of the target control code set.

9. The semiconductor memory device of claim 7, wherein:
the power selection signal is provided from an external memory controller or the command decoder, and
the power selection signal is associated with an operating frequency of the plurality of memory dies.

10. The semiconductor memory device of claim 7, wherein the calibration circuit includes:
a first code generator configured to generate a first pull-up control code of the first control code set or a second pull-up control code of the second control code set based on comparing a target output high level (VOH) voltage with a first voltage at a first node, the first node being between a pull-up driver and a replica pull-down driver;
a first code storing circuit configured to store the first pull-up control code or the second pull-up control code based on the target VOH voltage being equal to the first voltage;
a second code generator configured to generate a first pull-down control code of the first control code set or a second pull-down control code of the second control code set based on comparing a reference voltage with a second voltage at a second node, the second node being connected to the first impedance pad; and
a second code storing circuit configured to store the first pull-down control code or the second pull-down control code based on the reference voltage being equal to the second voltage.

11. The semiconductor memory device of claim 10, wherein the first code storing circuit includes:
a comparator configured to generate the first comparison signal by comparing the target VOH voltage with the first voltage at the first node; and
a counter configured to
receive the first power supply voltage and generate the first pull-up control code by counting the first comparison signal, and
receive the second power supply voltage and generate the second pull-up control code by counting the first comparison signal.

12. The semiconductor memory device of claim 11, wherein the counter includes:
a sub-counter configured to generate a counted value by counting the first comparison signal;
a first inverter connected between the first power supply voltage and a ground voltage or between the second power supply voltage and the ground voltage, the first inverter being configured to invert the counted value; and
a second inverter connected between the first power supply voltage and the ground voltage or between the second power supply voltage and the ground voltage, the second inverter being configured to output the first pull-up control code or the second pull-up control code by inverting an output of the first inverter.

13. The semiconductor memory device of claim 6,
wherein the master die includes a data output circuit configured to output a data signal by driving data based on a pull-up control code and a pull-down control code, and
wherein the data output circuit includes:
a pre-driver configured to receive the first power supply voltage or the second power supply voltage and generate a pull-up driving signal and a pull-down driving signal by driving the data based on the pull-up control code and the pull-down control code, respectively; and
the first output driver configured to output the data signal based on the pull-up driving signal and the pull-down driving signal.

14. The semiconductor memory device of claim 1, wherein the first slave die includes:
an impedance calibration circuit connected to the external resistor through a second impedance pad; and
a power selection circuit configured to
receive the first power supply voltage and the second power supply voltage,
provide the first power supply voltage to the impedance calibration circuit, and
provide, based on the second done signal, the second power supply voltage to the impedance calibration circuit.

15. The semiconductor memory device of claim 14, wherein the impedance calibration circuit includes:
a calibration controller configured to receive the first done signal through the second communication pad;
a calibration circuit connected to the external resistor through the second impedance pad; and
a code selection circuit,
wherein the calibration circuit is configured to:
perform a second impedance calibration operation to determine the third control code set or the fourth control code set in response to a calibration enable signal from the calibration controller; and
provide the calibration controller with a first comparison signal and a second comparison signal indicating that the second impedance calibration operation is completed,
wherein the code selection circuit is configured to:
latch the third control code set based on the first power supply voltage being provided to the calibration circuit;
latch the fourth control code set based on the second power supply voltage being provided to the calibration circuit; and
based on a power selection signal, provide, as a target control code set, the second output driver with one of the latched third control code set and the latched fourth control code set, and
wherein the calibration controller is configured to transmit, through the second communication pad and based on the first comparison signal and the second comparison signal, the second done signal to a second slave die of the plurality of slave dies that is adjacent to the first slave die.

16. The semiconductor memory device of claim 1, comprising a power management integrated circuit configured to provide the first power supply voltage and the second power supply voltage to the plurality of memory dies,
wherein the master die and the first slave die are configured to, based on the plurality of memory dies operating with a first frequency, determine the first control code set and the third control code set based on the first power supply voltage, respectively, and
wherein the master die and the first slave die are configured to, based on the plurality of memory dies operating with a second frequency higher than the first frequency, determine the second control code set and the fourth control code set based on the second power supply voltage, respectively, the second power supply voltage being greater than the first power supply voltage.

17. The semiconductor memory device of claim 1, wherein:
the master die is on the board;
the plurality of slave dies are stacked on the master die; and
the master die is connected to each slave die of the plurality of slave dies through a respective wire of a plurality of wires.

18. A memory system comprising:
a semiconductor memory device including a plurality of memory dies; and
a memory controller configured to control the semiconductor memory device, and
wherein the semiconductor memory device includes:
an external resistor in a board; and
the plurality of memory dies on the board, the plurality of memory dies including a master die and a plurality of slave dies,
wherein the master die includes a first output driver and a first communication pad, and the master die is configured to during an impedance calibration interval:
determine, based on a first power supply voltage, a first control code set associated with the first output driver;
latch the first control code set;
generate a first done signal indicating that the first control code set is determined;
transmit the first done signal to a first slave die of the plurality of slave dies through the first communication pad;
based on the first done signal, determine a second control code set associated with the first output driver based on a second power supply voltage; and
latch the second control code set.

19. The memory system of claim 18,
wherein the first slave die is adjacent to the master die, and the first slave die includes a second output driver and a second communication pad,
wherein the first slave die is configured to:
receive, from the master die, the first done signal through the second communication pad;
based on the first done signal, determine, based on the first power supply voltage, a third control code set associated with the second output driver;
latch the third control code set;
generate a second done signal indicating that the third control code is determined;
based on the second done signal, determine, based on the second power supply voltage, a fourth control code set associated with the second output driver; and
latch the fourth control code set,
wherein the master die is configured to perform a first impedance calibration operation to determine the first control code set or the second control code set based on an impedance calibration command from the memory controller, and
wherein the first slave die is configured to perform a second impedance calibration operation to determine the third control code set or the fourth control code set based on the first done signal.

20. A memory die comprising:
an output driver;
an impedance calibration circuit connected to an external resistor through an impedance pad, the impedance calibration circuit being configured to during an impedance calibration interval:
determine, based on a first power supply voltage, a first control code set associated with a driving strength of the output driver;
latch the first control code set;
generate a first done signal indicating that the first control code set is determined;
transmit the first done signal through a communication pad;
based on the first done signal, determine, based on a second power supply voltage, a second control code set associated with the driving strength of the output driver; and
latch the second control code set;
a power selection circuit configured to receive the first power supply voltage and the second power supply voltage, provide the first power supply voltage to the impedance calibration circuit, and provide, based on the first done signal, the second power supply voltage to the impedance calibration circuit;
a data input/output (I/O) circuit including the output driver;
a first power switch configured to provide the first power supply voltage to the data I/O circuit based on a power selection signal; and
a second power switch configured to provide the second power supply voltage to the data I/O circuit based on an inverted version of the power selection signal.
